(19) United States
(12) Patent Application Publication
(10) Pub. No.: US 2008/0029144 A1
(43) Pub. Date: Feb. 7, 2008

(54) Supporting a solar energy collection device

(75) Inventors: Shay Donald Brazier, Auckland (NZ); Daniel Gower Davies, Bath (GB); Lachlan Samuel Bateman, London (GB); Guy Roderick Atherton, London (GB); Martyn John Charles Berry, Waterlooville (GB)

Correspondence Address: JAMES C. WRAY, 1493 CHAIN BRIDGE ROAD, SUITE 300, MCLEAN, VA, 22101, US

(73) Assignee: Solar Century Holdings Limited

(21) Appl. No.: 11/804,697

(22) Filed: May 18, 2007

(30) Foreign Application Priority Data
May 19, 2006 (GB) 06 10 031.7

(51) Int. Cl. H01L 35/00

(52) U.S. Cl. 136/206

(57) ABSTRACT

Apparatus is provided for supporting a solar energy collection device (601, 602). The apparatus is substantially wedge-shaped with a base (102) for contacting a roof surface (203) and an inclined front face (103) for supporting the device (601). The apparatus is configured such that the total weight is adjustable so as to apply an appropriate loading on the roof. In a first embodiment ballast is supplied to a ballast cavity (105). In an alternative embodiment, wedge-shaped members (903) may be selectively removed from an assembly so as to provide a desired weight distribution.

### CROSS REFERENCE TO RELATED APPLICATIONS

This application claims priority from United Kingdom Patent Application No. 06 10 031.7, filed 19 May 2006, the entire disclosure of which is incorporated herein by reference in its entirety.

### TECHNICAL FIELD

The present invention relates to apparatus for supporting a solar energy collection device, apparatus for the collection of solar energy and a method of applying solar collection devices to a flat or modestly sloping roof.

### BACKGROUND OF THE INVENTION

Mounting systems for supporting solar energy collection devices are known, many of which are configured to place the collection devices at particular inclinations and orientations, while at the same time providing a firm anchoring.

In many installations, the actual weight of the assembly is used to ensure that it remains in position on the roof, although additional fastening apparatus may be provided. However, care must be taken to ensure that the amount of force and loading applied to the roof does not become excessive while at the same time ensuring that the solar energy collection devices are not disturbed by the application of wind or other forces. Furthermore, it is also appreciated that it is preferable for the amount of effort required to install the devices to be minimised and a modular approach is preferred, so as to reduce the requirement for heavy lifting equipment.

### BRIEF SUMMARY OF THE INVENTION

A first aspect of the present invention provides apparatus for supporting a solar energy collection device. The apparatus is substantially wedge-shaped with a base for contacting the roof surface and an inclined front face for supporting the device. The apparatus is configured such that the total weight of the apparatus is adjustable so as to apply an appropriate loading to the roof.

By allowing the weight of each individual support device to be adjusted, it is possible to provide a variable roof loading so as to compensate for different portions of the roof receiving different degrees of wind uplift. Similarly, greater load may be applied at positions of greater strength.

In a preferred embodiment, the apparatus includes a compartment for receiving ballast, which may be in the form of a particular material or in the form of a liquid.

A second aspect of the invention provides apparatus mountable on a roof for collecting solar energy, comprising a solar energy collection device, a mounting plate for receiving said device and a plurality of substantially wedge-shaped supporting devices for supporting the mounting plate at an inclined angle. The supporting devices have a total weight that is adjustable so as to apply an appropriate loading to the roof.

In a preferred embodiment, the solar energy collection device is a photovoltaic device that may, for example, include crystalline cells secured in a panel device and cables may be provided for connecting a plurality of photovoltaic devices, each supported by respective supporting devices.

A third aspect of the present invention provides a method of applying solar energy collection devices to a flat or modestly sloping roof. A plurality of substantially wedge-shaped devices are applied upon the roof in an appropriate north-south orientation. The total weight of the wedge-shaped devices is adjusted so as to apply an appropriate loading on to the roof. Preferably the loading is adjusted so as to withstand wind uplift while minimising excessive loading upon the roof. A mounting plate is secured to the adjusted devices and the solar energy collection devices are positioned upon the mounting plate. Further securing devices, such as rails, may be provided to further secure the mounting plate to the roof.

In addition, wind baffles or similar devices may be attached, possibly to a rear surface of a mounting plate, so as to minimise wind uplift.

The devices may make use of an integral compass to determine the north-south orientation and the adjustment of weight may involve adding material to at least one of the devices or, alternatively, removing material from the devices.

### BRIEF DESCRIPTION OF THE SEVERAL VIEWS OF THE DRAWINGS

FIG. 1 shows a device for supporting a solar energy collection panel;

FIG. 2 shows a support device being applied to a roof;

FIG. 3 shows a plurality of support devices applied to a roof;

FIG. 4 shows a front view of a mounting plate;

FIG. 5 shows a rear view of a mounting plate;

FIG. 6 shows examples of solar arrays that can be attached to a mounting plate;

FIG. 7 shows the relationship between a support device and a mounting plate;

FIG. 8 shows the system installed on a roof;

FIG. 9 shows an alternative example of apparatus embodying the present invention; and

FIG. 10 shows a variation on the apparatus shown in FIG. 9.

### DESCRIPTION OF THE BEST MODES FOR CARRYING OUT THE INVENTION

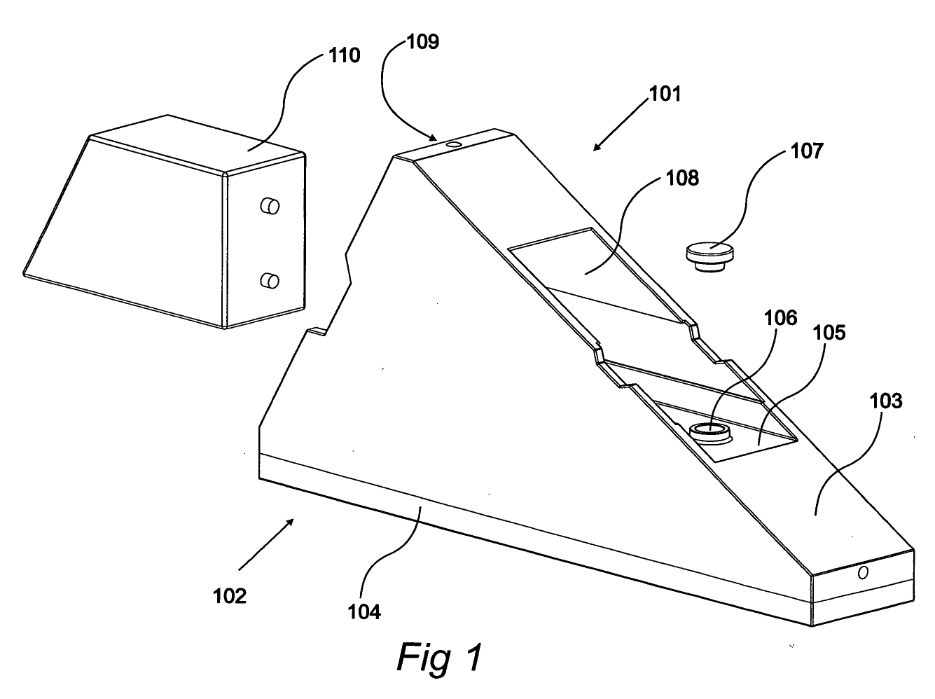

A device 101 for supporting a solar energy collecting panel is illustrated in FIG. 1. The device 101 is substantially wedge-shaped with a base 102 for contacting a roof surface and an inclined front face 103 for supporting the solar energy collection panel or similar device.

The base 102 is covered with a high friction rubber mat 104 or similar material to resist slippage and to dampen vibration.

Preferably, additional attachment devices are provided to enhance the stability of the mounting but in a preferred embodiment the support is held in place predominantly by gravity and friction.

In a preferred embodiment, the support is moulded in a plastic material and as such is relatively light, allowing the support to be positioned on a roof manually and preferably without the use of heavy lifting equipment. The device is configured such that the total weight may be adjusted. Consequently, the device may be placed in position on a roof and then ballast may be added in order to increase the weight. In this way, an appropriate weight is provided by the device but at the same time, without the ballast being added, the device is relatively light thereby facilitating its manual application.

In the embodiment shown in FIG. 1, a ballast cavity 105 is provided towards the bottom of the device configured to receive ballast after the device has been located in position. Ballast, which may take the form of a liquid (such as water) or as particulate matter (such as sand) is applied to the ballast cavity 105 via a filler hole 106. The amount of ballast supplied to the ballast cavity 105 may be adjusted such that in combination, the wedge-shaped device with its ballast provides an optimised degree of loading to the roof surface. An optimised degree of loading is sufficient to withstand wind uplift while at the same time minimising any excessive loading applied to the roof. After filling the ballast cavity, the filler hole 106 is secured by a filler cap 107.

Above the ballast cavity 105 there is provided a passageway 108 that extends through the body of the support device 101 from the front face 103 to the rear face 109. The passageway 108 is provided so as to house electrical devices, illustrated generally in FIG. 1 as 110. These electrical devices 110 may take the form of electrical interconnection apparatus or may take the form of more sophisticated electronic apparatus, such as inverters for inverting the generated direct current to an alternating current for transmission purposes.

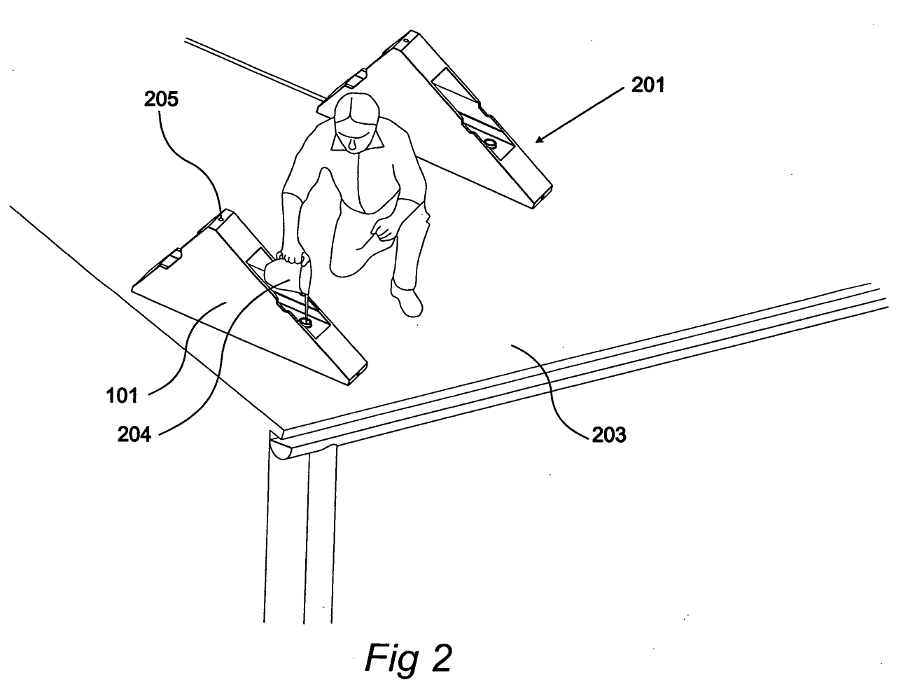

FIG. 2 shows the support device 101 with a similar support device 201 applied to a roof 203 of a commercial building. Typical of commercial buildings, the roof is relatively large and is either flat or, as in this example, has a modest incline. In this example, ballast is being applied to the ballast cavity 105 via an applicator 204. The applicator 204 allows appropriate quantities of ballast to be measured, based on calculations as to the degree of loading required by the support device so as to ensure that the support device remains stable while at the same time the weight of the support device does not apply excessive loading to the roof.

In order to achieve optimal solar collection, it is preferable for the width of the device to be aligned in a substantially north-south direction. To facilitate this alignment, each device may be provided with a compass 205, thereby allowing an installer to accurately align each device without a requirement for additional equipment.

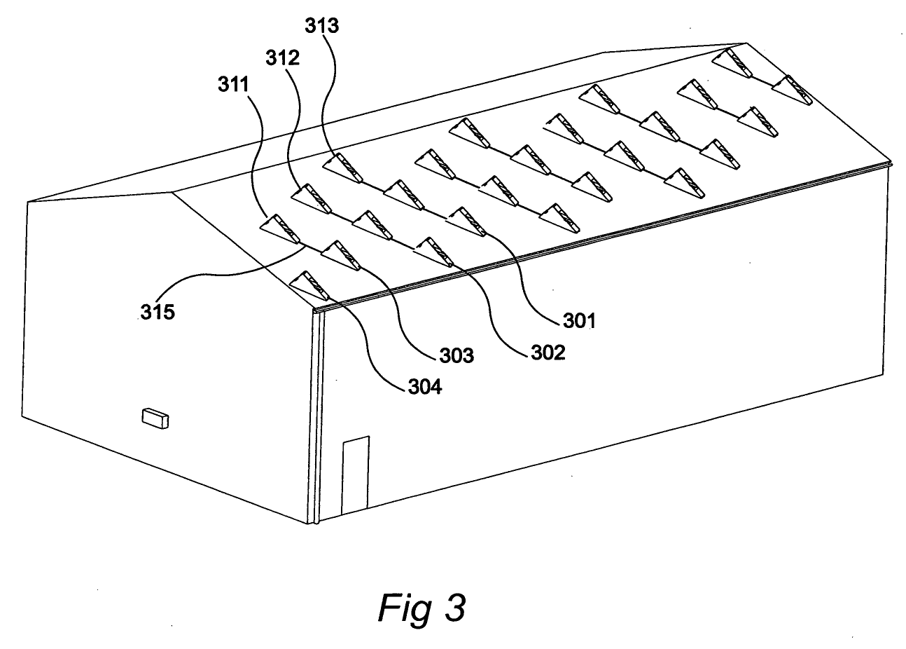

FIG. 3 shows how a plurality of the support devices may be applied to a roof so as to optimise the collection of solar energy from said roof.

In a preferred embodiment, a row of supports 301, 302, 303, 304, 305 receive panels which are subsequently connected together, thereby creating a contiguous run of panels. Similarly, panels are connected together after being applied to supports 311, 312 and 313.

In a preferred embodiment, support devices are aligned in a column, such as devices 311 and 303, are connected by a conduit 315. This conduit enhances structural stability and also allows electrical connections to be made between adjacent rows, to facilitate the collection of electrical energy at a single output. Furthermore, it is possible for these conduits to be pre-cut to a preferred length, thereby facilitating the installation of the support devices at optimised spacings, as illustrated in FIG. 3, so as to avoid self-shading.

As illustrated in FIG. 3, the preferred embodiment facilitates the application of photovoltaic devices to a flat or modestly sloping roof, in which a plurality of substantially wedge-shaped devices are applied to the roof in an appropriate north-south orientation. The total weight of the devices is adjusted so as to apply an appropriate loading to the roof. Thereafter, a mounting plate is secured to the appropriately adjusted devices and solar energy collection devices, preferably photovoltaic devices, are positioned upon the mounting plate.

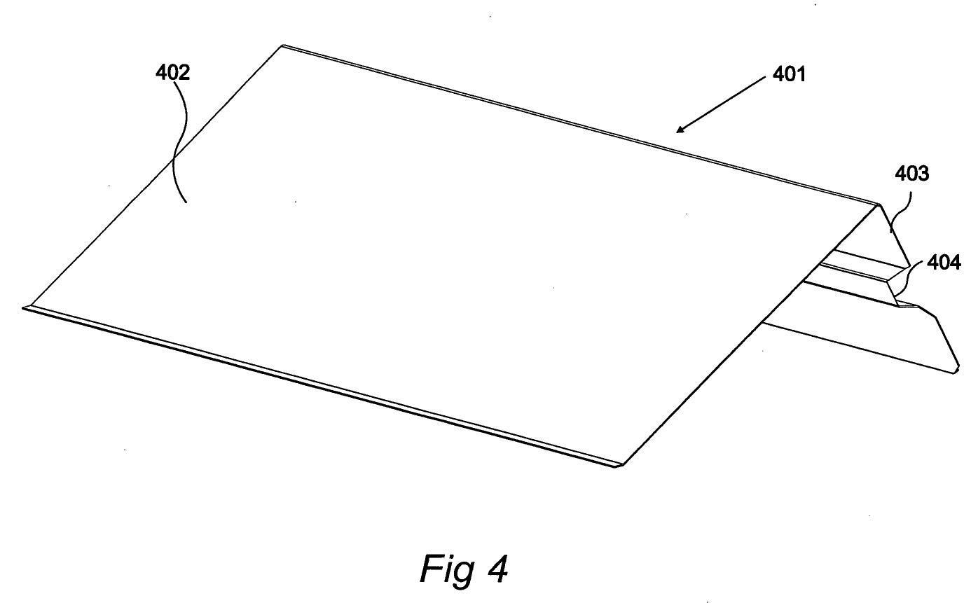

FIG. 4 illustrates an appropriate mounting plate for application to the devices illustrated in FIG. 3. The mounting plate 401 includes a front face 402 and a support web 403. As shown in FIG. 4, the angle between the front face 402 and the support web 403 reflects that defined by the wedge-shaped supports themselves and is thereby held firmly by the wedge-shaped supports. Depending upon the configuration, mechanical fixing may be required between the wedge-shaped supports and the mounting plate. In this example, wedge-shaped supports 101 are provided at each end of the mounting plate 401. However, if additional loading is required, it would be possible for additional intermediate support devices to be provided.

The support web 403 includes a channel 404 to facilitate the housing of interconnection cables.

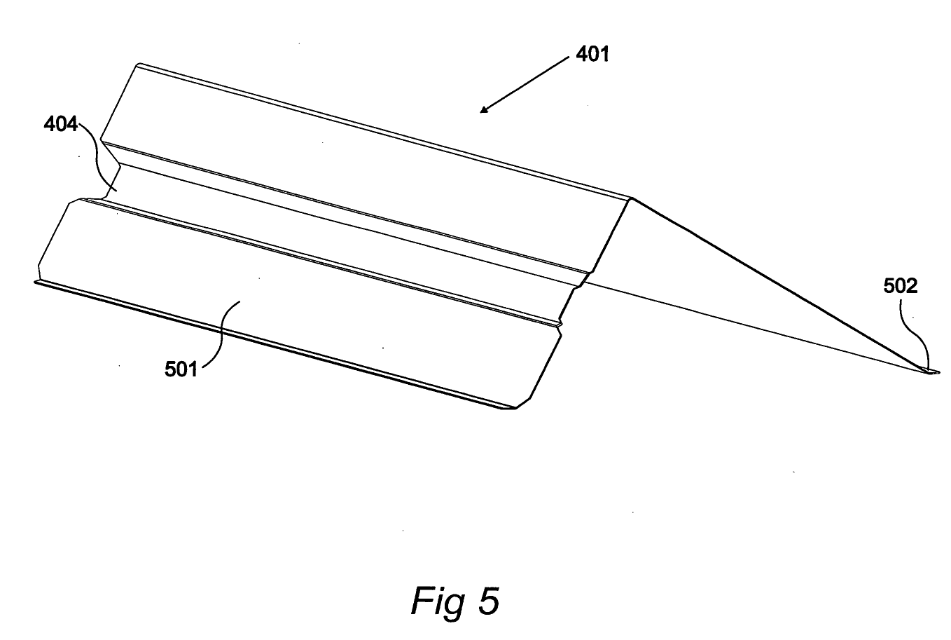

FIG. 5 shows the mounting plate 401 from the rear, clearly showing channel 404 for conveying interconnection cables. In addition, the support web is provided with a substantially flat lip 501 which may be used to facilitate additional securing to the roof 203. A similar lip 502 is provided at the end of the front face 402.

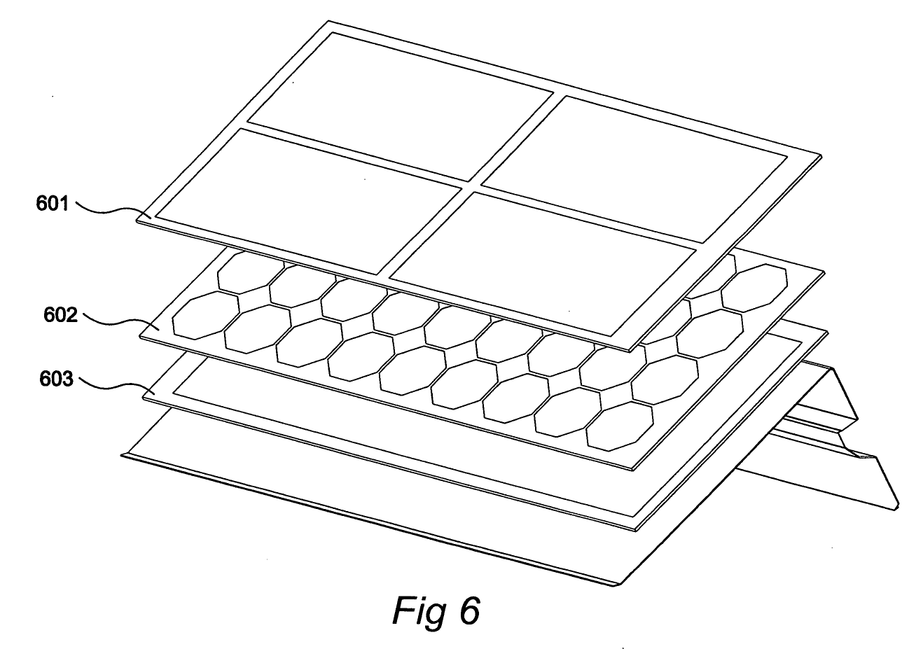

FIG. 6 shows how, in a preferred embodiment, solar arrays are attached to the front face of the mounting plate 401, this could be attached onsite or in the factory during manufacture. A choice range of photovoltaic systems could be deployed, such as photovoltaic modules 601, crystalline cell laminates 602 or thin film amorphous laminates 603.

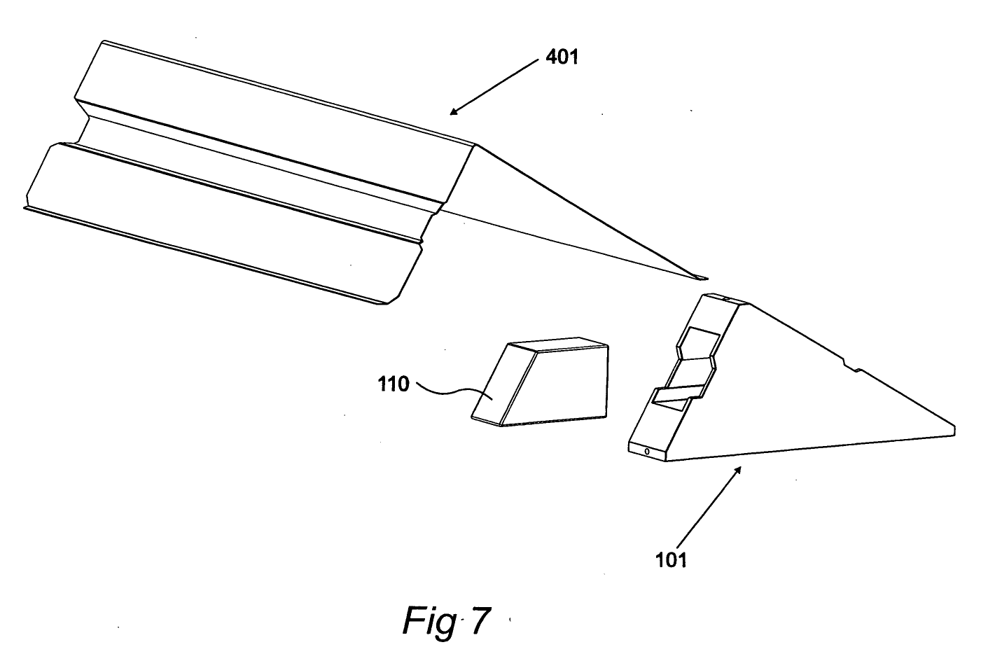

FIG. 7 illustrates the interconnecting relationship between the mounting plate 401 and the support devices 101. Preferably, the support devices 101 are wide enough to support adjacent edges of two mounting plates 401, thereby enabling long rows of photovoltaic arrays to be set up in order to optimise the collection of solar energy from the available roof space. As previously stated, intermediate support devices may be provided as required.

After aligning the support devices as illustrated in FIG. 3, some of the devices may be required to receive an electrical connection device 110 and, preferably, these are inserted where required before the application of the mounting plates 401. However, in a preferred embodiment, the electronic equipment should remain accessible after the mounting plate has been fitted so as facilitate further access and maintenance. Mounting plates 401 are then applied so as to be supported by at least two supporting devices and secured further (where appropriate) using lips 501, 502.

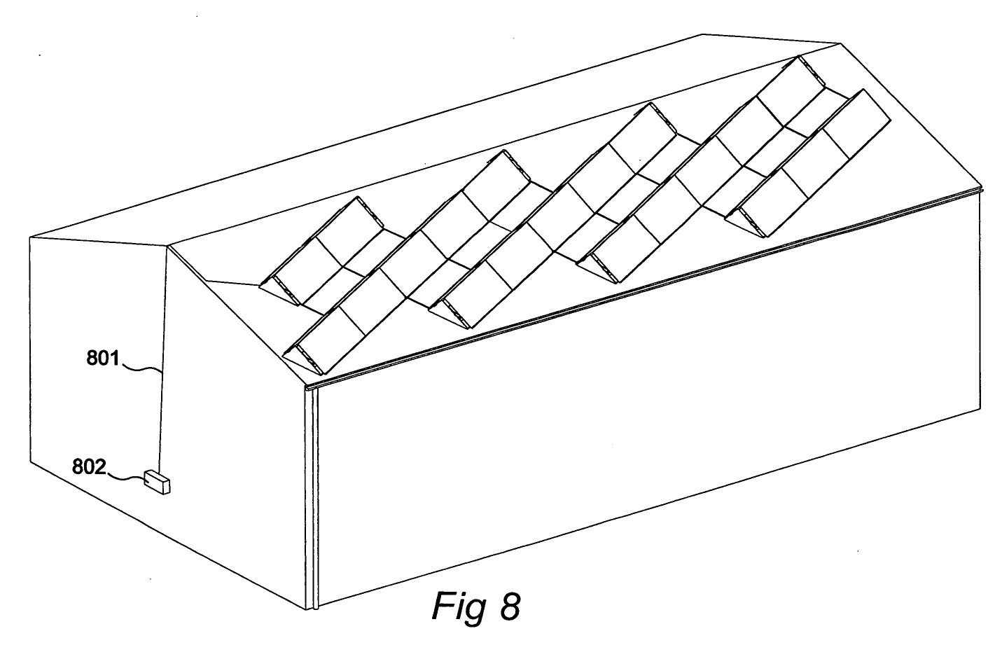

The modular installation of the support devices with mounting plates attached thereto allows an entire system, as illustrated in FIG. 8, to be established without the use of heavy lifting equipment. It is envisaged that in a preferred embodiment, the whole system could be configured by two installers, preferably followed by an electrician, to complete the electrical installation. The mechanical mounting plates are configured as illustrated in FIG. 8, with appropriate photovoltaic systems provided pre-fitted or deployed on-site as appropriate in a fashion substantially similar to that illustrated in FIG. 6. Upon completion of the mechanical installation, an electrician would interconnect the energy generating devices and deploy additional electronic equipment as required. As illustrated in FIG. 8, the transmission cable 801 is received from the array of devices and returned to the interior of the building, via an appropriate interconnection box 802 so as to allow the generated electricity to be used within the building. In a preferred embodiment, the electricity generated from the array is supplied as a dual supply together with mains power received from a grid system. Alternatively, the generated electricity may be supplied directly to a grid system.

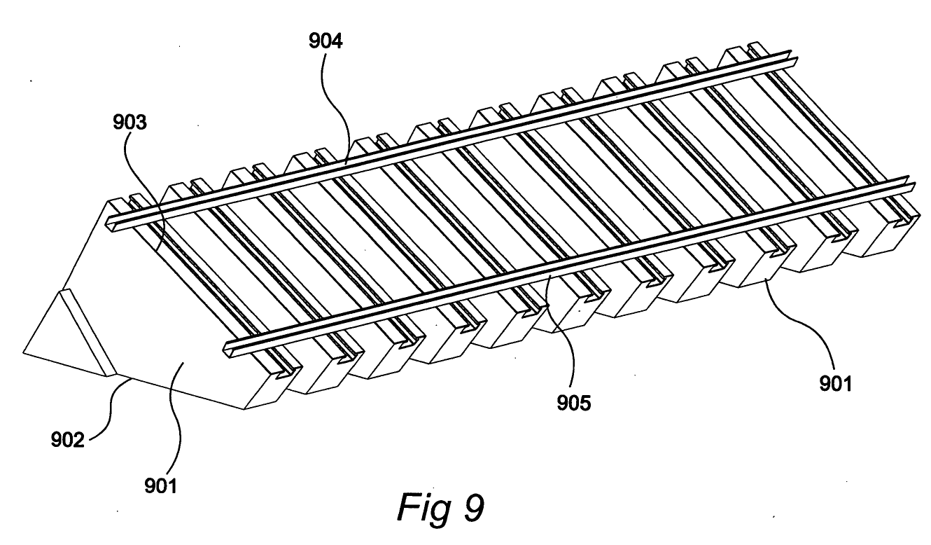

FIG. 9 shows an alternative apparatus 901 for supporting a solar energy collection device which is also substantially wedge-shaped, with a base 902 for contacting a roof surface and an inclined front face 903 for supporting solar energy collection devices. Each wedge-shaped component 901 is produced from a solid plastic or rubber material (possibly recycled rubber) with an upper connecting rail 904 and a lower connecting rail 905 attaching the wedge-shaped devices 901 together, thereby defining the whole assembly.

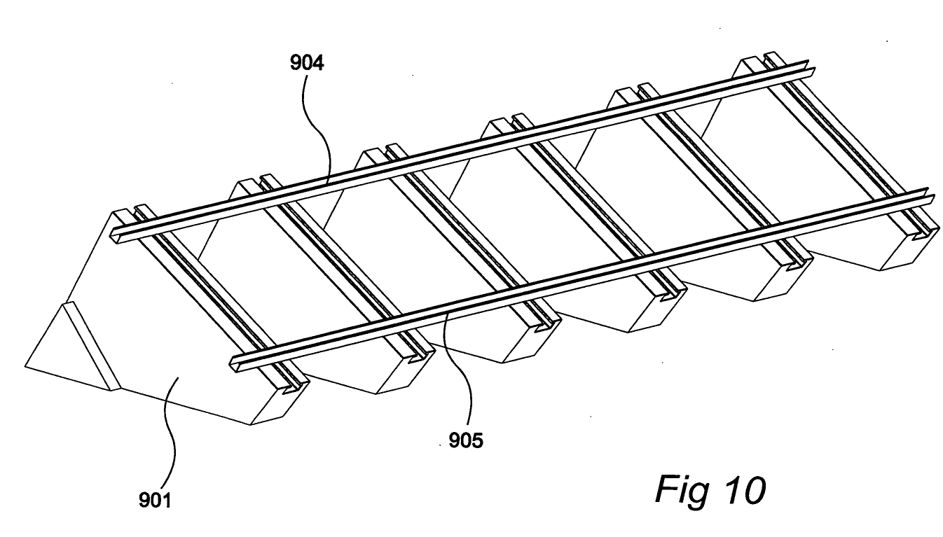

FIG. 10 shows how individual wedge-shaped units 901 may be deployed along rail 904. During assembly, an appropriate number of wedge-shaped units 901 are deployed on a roof. More units would be deployed if a greater loading is required. Thereafter, having positioned the wedge-shaped units, rails 904 and 905 are located and firmly attached to the units. Thus, when heavy loading is required a configuration may take the form as shown in FIG. 9 or, with a lighter loading, the configuration may take the form as shown in FIG. 10. It is therefore possible to adjust the total weight of the wedge-shaped devices so as to apply an appropriate loading to the roof.

1. Apparatus for supporting a solar energy collection device, wherein:
said apparatus is substantially wedge-shaped with a base for contacting a roof surface and an inclined front face for supporting said device; and
said apparatus is configured such that the total weight of the apparatus is adjustable so as to apply loading on said roof to withstand wind uplift forces.

2. Apparatus according to claim 1, wherein said apparatus includes a compartment for receiving ballast.

3. Apparatus according to claim 2, wherein said compartment is configured to receive a particulate material or a liquid as ballast.

4. Apparatus according to claim 1, wherein said apparatus is constructed from a moulded plastics material.

5. Apparatus according to claim 1, including a passageway that extends into the apparatus from said front face.

6. Apparatus according to claim 1, wherein a plurality of wedge-shaped devices are provided and the total weight of the apparatus is adjusted by adjusting the number of wedge-shaped devices present in an installation.

7. Apparatus according to claim 6, wherein said wedge-shaped devices are connected together by connecting rails.

8. Apparatus according to claim 7, wherein said members are moulded in rubber or plastic.

9. Apparatus according to claim 6, wherein said rubber or plastic is substantially solid.

10. Apparatus according to claim 1, wherein the solar energy collecting device is a photo-voltaic device.

11. Apparatus according to claim 1, including a back face between said base and said front face, wherein a channel is formed in said back face.

12. Apparatus mountable on a roof for collecting solar energy, comprising:
a solar energy collection device;
a mounting plate for receiving said solar energy collection device; and
a plurality of substantially wedge-shaped supporting devices for supporting said mounting plate at an inclined angle, wherein said supporting devices have a total weight that is adjustable so as to apply an appropriate loading on said roof.

13. Apparatus according to claim 2, wherein said solar energy collection is a solar thermal device or a photovoltaic device, possibly consisting of crystalline cells secured in a panel device or consisting of thin film amorphous technology.

14. Apparatus according to claim 12, including cables for connecting a plurality of photo-voltaic devices, each supported by respective supporting devices.

15. A method of applying solar energy collection devices to a flat or modestly sloping roof, comprising the steps of:
applying a plurality of substantially wedge-shaped devices upon said roof in an appropriate north-south orientation;
adjusting the total weight of said wedge-shaped devices so as to apply an appropriate loading on said roof;
securing a mounting plate with solar energy collection device incorporated to said adjusted devices or positioned upon said mounting plate.

16. A method according to claim 15, wherein the applying of said devices makes use of integral compasses to determine said north-south orientation.

17. A method according to claim 15, wherein said adjusting of total weight involves adding material to at least one of said devices.

18. A method according to claim 17, wherein particulate matter or a liquid is used for adding weight.

19. A method according to claim 15, wherein an electrical component is added to at least one of wedge-shaped devices.

20. A method according to claim 19, wherein said added electrical component is a junction box.

21. A method according to claim 15, wherein the adjusting of total weight involves removing material.

22. A method according to claim 21, wherein one or more of said wedge-shaped devices are removed from a plurality of connected devices.

23. A method according to claim 15, including the step of running cables through channels defined in back surfaces of said wedge-shaped devices.
